(19) United States
(12) Patent Application Publication
(10) Pub. No.: US 2025/0038066 A1
(43) Pub. Date: Jan. 30, 2025

(54) INTEGRATION OF SEMICONDUCTOR DEVICE ASSEMBLIES WITH THERMAL DISSIPATION MECHANISMS

(71) Applicant: SEMICONDUCTOR COMPONENTS INDUSTRIES, LLC, Scottsdale, AZ (US)

(72) Inventors: Shutesh KRISHNAN, Negeri Sembilan (MY); Chee Hiong CHEW, Seremban (MY); Yusheng LIN, Phoenix, AZ (US); Roveendra PAUL, Dublin, CA (US)

(73) Assignee: SEMICONDUCTOR COMPONENTS INDUSTRIES, LLC, Scottsdale, AZ (US)

(21) Appl. No.: 18/359,259

(22) Filed: Jul. 26, 2023

(51) Int. Cl. H01L 23/373; H01L 23/427

(52) U.S. Cl. CPC H01L 23/3737; H01L 23/3731; H01L 23/4275

(57) ABSTRACT

In a general aspect, a semiconductor device assembly includes a metallic chamber configured to transfer thermal energy from a first surface of the metallic chamber to a second surface of the metallic chamber opposite the first surface, a thermally conductive polymer layer disposed on the first surface of the metallic chamber, a patterned metal layer disposed on the thermally conductive polymer layer, and at least one semiconductor die disposed on the patterned metal layer.

### TECHNICAL FIELD

This description relates to semiconductor device assemblies. More specifically, this description relates to semiconductor device assemblies (e.g., semiconductor device modules) with improved thermal dissipation performance.

### BACKGROUND

Semiconductor device assemblies, such as assemblies including power semiconductor devices (which can be referred to as power modules, multi-chip power modules, etc.), can be implemented using semiconductor die, substrates (e.g., direct-bonded metal substrates, ceramic substrates, and so forth), wire bonds, etc. Such semiconductor device assemblies can be coupled with a thermal dissipation mechanism, appliance, device, apparatus, etc. (e.g., a heat sink, a water jacket, etc.), that can dissipate heat generated during operation of included semiconductor devices (die).

### SUMMARY

In a general aspect, a semiconductor device assembly includes a metallic chamber configured to transfer thermal energy from a first surface of the metallic chamber to a second surface of the metallic chamber opposite the first surface, a thermally conductive polymer layer disposed on the first surface of the metallic chamber, a patterned metal layer disposed on the thermally conductive polymer layer, and at least one semiconductor die disposed on the patterned metal layer.

Implementations can include one or more of the following features, alone or in combination. For example, the thermally conductive polymer layer can include a cured polymer resin and thermally conductive nanoparticles. The thermally conductive nanoparticles can include ceramic nanoparticles. The thermally conductive nanoparticles include graphite nanoparticles.

The metallic chamber can include a vacuum chamber and an evaporative-cooled heat pipe disposed in the vacuum chamber.

The first surface of the metallic chamber can be arranged in a plane. The evaporative-cooled heat pipe can be arranged along a longitudinal axis parallel to the plane.

The evaporative-cooled heat pipe can be a first evaporative-cooled heat pipe. The metallic chamber can include a second evaporative-cooled heat pipe. The first evaporative-cooled heat pipe can be arranged along a first longitudinal axis orthogonal to the plane of the first surface of the metallic chamber, and the second evaporative-cooled heat pipe can be arranged along a second longitudinal axis parallel to the first longitudinal axis.

The semiconductor device assembly can include a fluidic cooling jacket disposed on the second surface of the metallic chamber.

In another general aspect, a semiconductor device assembly includes a first metallic chamber configured to transfer thermal energy from a first surface of the first metallic chamber to a second surface of the first metallic chamber opposite the first surface. The assembly further includes a second metallic chamber configured to transfer thermal energy from a first surface of the second metallic chamber to a second surface of the second metallic chamber opposite the first surface. The assembly also includes a first thermally conductive polymer layer disposed on the first surface of the first metallic chamber, a second thermally conductive polymer layer disposed on the first surface of the second metallic chamber, a first patterned metal layer disposed on the first thermally conductive polymer layer, and a second patterned metal layer disposed on the second thermally conductive polymer layer. The assembly further includes a first semiconductor die disposed on the first patterned metal layer, a second semiconductor die disposed on the second patterned metal layer, a first electrically conductive spacer disposed on the first patterned metal layer and electrically coupled with the second semiconductor die, and a second electrically conductive spacer disposed on the second patterned metal layer and electrically coupled with the first semiconductor die.

Implementations can include one or more of the following features, alone or in combination. For example, the first thermally conductive polymer layer and the second thermally conductive polymer layer can include a cured polymer resin and thermally conductive nanoparticles. The thermally conductive nanoparticles can include at least one of ceramic nanoparticles or graphite nanoparticles.

The first metallic chamber can include a first vacuum chamber and a first evaporative-cooled heat pipe disposed in the first vacuum chamber. The second metallic chamber can include a second vacuum chamber and a second evaporative-cooled heat pipe disposed in the second vacuum chamber.

The first surface of the first metallic chamber can be arranged in a plane. The first evaporative-cooled heat pipe can be arranged along a first longitudinal axis parallel to the plane, and the second evaporative-cooled heat pipe can be arranged along a second longitudinal axis parallel to the plane. The first evaporative-cooled heat pipe can be arranged along a first longitudinal axis orthogonal to the plane, and the second evaporative-cooled heat pipe can be arranged along a second longitudinal axis orthogonal to the plane.

The first metallic chamber can further include a third evaporative-cooled heat pipe disposed in the first vacuum chamber; and the second metallic chamber can include a fourth evaporative-cooled heat pipe disposed in the second vacuum chamber. The first evaporative-cooled heat pipe, the second evaporative-cooled heat pipe, the third evaporative-cooled heat pipe and the fourth evaporative-cooled heat pipe being arranged along respective longitudinal axes that are parallel to one another. The first surface of the first metallic chamber can be arranged in a plane, and the respective longitudinal axes can be orthogonal to the plane of the first metallic chamber.

The assembly can include a first fluidic cooling jacket disposed on the second surface of the first metallic chamber, and a second fluidic cooling jacket disposed on the second surface of the second metallic chamber.

In another general aspect, a method for producing a semiconductor device assembly includes forming (e.g., printing), on a surface of a metallic chamber including an evaporative-cooled heat pipe, a layer of thermally conductive polymer resin, and disposing a metal layer on the layer of thermally conductive polymer resin. The method further includes curing the layer of thermally conductive polymer resin. The method also includes, after curing the layer of thermally conductive polymer resin, producing a semiconductor device circuit on the metal layer.

Implementations can include one or more of the following features, alone or in combination. For example, producing the semiconductor device circuit can include patterning the metal layer to produce a patterned metal layer, coupling at least one semiconductor die with the patterned metal layer, and forming electrical connections of the semiconductor device circuit.

Curing the layer of thermally conductive polymer resin can adhere the metal layer to the layer of thermally conductive polymer resin.

### BRIEF DESCRIPTION OF THE DRAWINGS

FIG. 1 is a block diagram schematically illustrating a side view of an example semiconductor device assembly.

FIGS. 2A and 2B are diagrams illustrating side views of an example semiconductor device assembly.

FIG. 3A is a diagram illustrating a side view of another example semiconductor device assembly.

FIG. 3B is a diagram illustrating a portion of the semiconductor assembly of FIG. 3A.

FIG. 4 is a diagram illustrating a side view of yet another example semiconductor device assembly.

FIG. 5 is a diagram illustrating a side view of still another example semiconductor device assembly.

FIG. 6 is a flowchart illustrating an example method for producing a semiconductor device assembly, such as the assemblies of FIGS. 1, 2A-2B, 3A, 4 and 5.

In the drawings, which are not necessarily drawn to scale, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings, but are provided for context between related views. Also, not all like elements in the drawings are specifically referenced with a reference symbol when multiple instances of an element are illustrated.

### DETAILED DESCRIPTION

This disclosure relates to implementations of electronic device assemblies, e.g., power semiconductor device assemblies, such as multichip modules (MCMs) with direct cooling. Such assemblies can be used in, e.g., automotive applications, industrial applications, etc. For instance, the implementations described herein can be implemented in high-power modules, such as power converters, ignition circuits, power transistor pairs, etc.

In prior implementations, semiconductor device assemblies are coupled with a respective thermal dissipation mechanism using a thermal-interface material (TIM). Such approaches have certain drawbacks, however. For instance, materials that are used for TIM (e.g., thermal grease) can have a relatively high thermal resistance (e.g., as compared to a thermal resistance of an associated thermal dissipation mechanism), which can increase thermal resistance and reduce an overall cooling efficiency (e.g., heat dissipation efficiency) of such implementations. In other prior implementations, a substrate, such as a direct-bonded metal substrate, can be coupled with a thermal dissipation mechanism using a cladding or brazing process. Such processes are performed at temperatures in excess of 1000 degrees Celsius, which can damage the substrate or other elements of an associated assembly.

In the implementations described herein, a thermally conductive polymer compound is formed on a thermal dissipation device, such as a metallic chamber including one or more evaporative-cooled heat pipes. The thermally conductive polymer layer can include a cured polymer resin that is mixed (infiltrated, blended, compounded, etc.) with thermally conductive nanoparticles. Such nanoparticles can include boron nitride, aluminum nitride, aluminum oxide, other ceramic and/or oxide materials, graphite, graphene, etc. In implementations using graphite and/or graphene, the graphite/graphene is functionalized such that chemically bonds with the polymer, which acts as a carrier material (for graphite/graphene, ceramics, or other materials). Such functionalization of graphite/graphene makes it electrically insulating, rather than being electrically conductive.

A patterned metal layer is disposed on (adhered to) the thermally conductive polymer layer. A semiconductor circuit is the formed on the patterned metal layer (and the thermally conductive polymer layer). Accordingly, in implementations described herein, a ceramic substrate and an associated thermal interface material (TIM) for coupling the substrate with a thermal dissipation device can be omitted. Such implementations can improve thermal dissipation efficiency, as a thermally conductive polymer layer can have a thermal conductivity of greater than 300 Watts per meter-Kelvin (W/mK) as compared to, e.g., a thermal grease TIM, which has a thermal conductivity of 35 W/mK or less.

Furthermore, the approaches described herein reduce high temperature processing during assembly of an electronic device assembly and, therefore, can reduce or eliminate associated damage. For instance, a thermally conductive polymer layer can be cured at a temperature of 200 to 500 degrees Celsius (C), as compared to prior implementations where a ceramic substrate can be coupled with a thermal dissipation device using a cladding or brazing process that is performed at 1000° C. or greater.

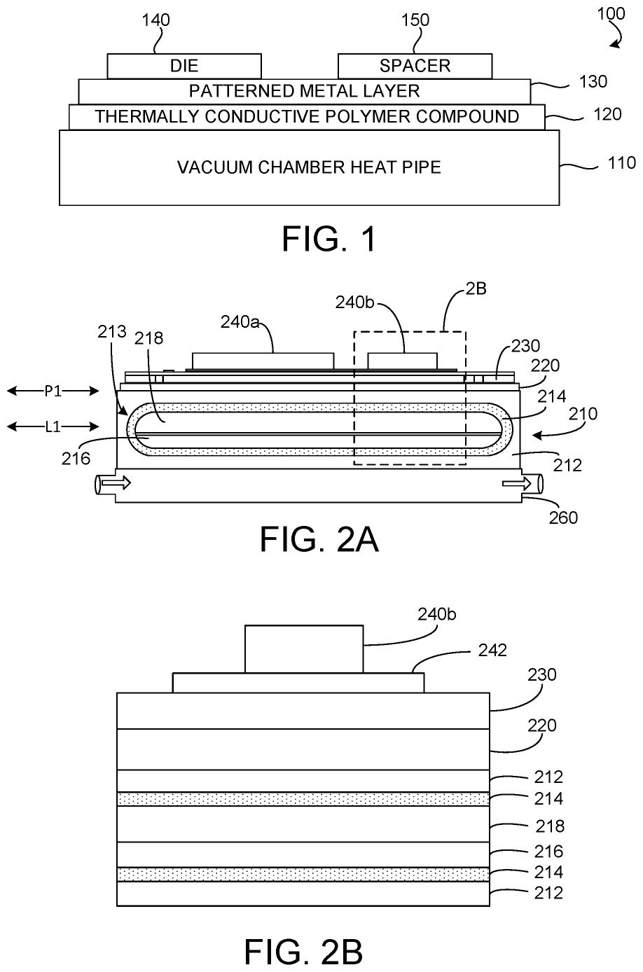

FIG. 1 is a block diagram schematically illustrating a side view of an example semiconductor device assembly (assembly 100). As shown in FIG. 1, the assembly 100 includes a vacuum chamber heat pipe 110, which operates as a thermal dissipation device of the assembly 100. The structure of the vacuum chamber heat pipe 110 will depend on the particular implementation. For instance, in some implementations, the vacuum chamber heat pipe 110 can be a metallic vacuum chamber (e.g., copper, aluminum copper, etc.) that includes one or more evaporative cooling pipes. The vacuum chamber heat pipe 110 is configured to transfer heat, e.g., from a top surface to a bottom surface of the vacuum chamber heat pipe 110 in the orientation shown in FIG. 1. In other words, the vacuum chamber heat pipe 110, during operation of a semiconductor device circuit disposed on vacuum chamber heat pipe 110, heat generated by the circuit is transferred from the surface including the circuit to an opposite surface.

As shown in FIG. 1, the assembly 100 also includes a thermally conductive polymer compound 120 (a thermally conductive polymer layer), a patterned metal layer 130, a semiconductor die 140 and a spacer 150. As described herein, the thermally conductive polymer compound 120 can include a cured polymer resin that is mixed with thermally conductive nanoparticles. The thermally conductive nanoparticles can include ceramics, oxides, functionalized graphitegraphene, etc. For instance, an uncured (e.g., viscous) polymer resin and nanoparticle mixture can be applied to the vacuum chamber heat pipe 110 using a printing process. The patterned metal layer 130 can be pre-patterned or, alternatively, can be patterned in-situ. If the patterned metal layer 130 is pre-patterned, the thermally conductive polymer compound 120 can be cured after the patterned metal layer 130 is applied. If the patterned metal layer 130 is patterned in-situ, a metal layer (e.g., sheet, etc.) can be applied to the uncured resin mixture, a curing process can be performed, and the applied metal layer can then be patterned.

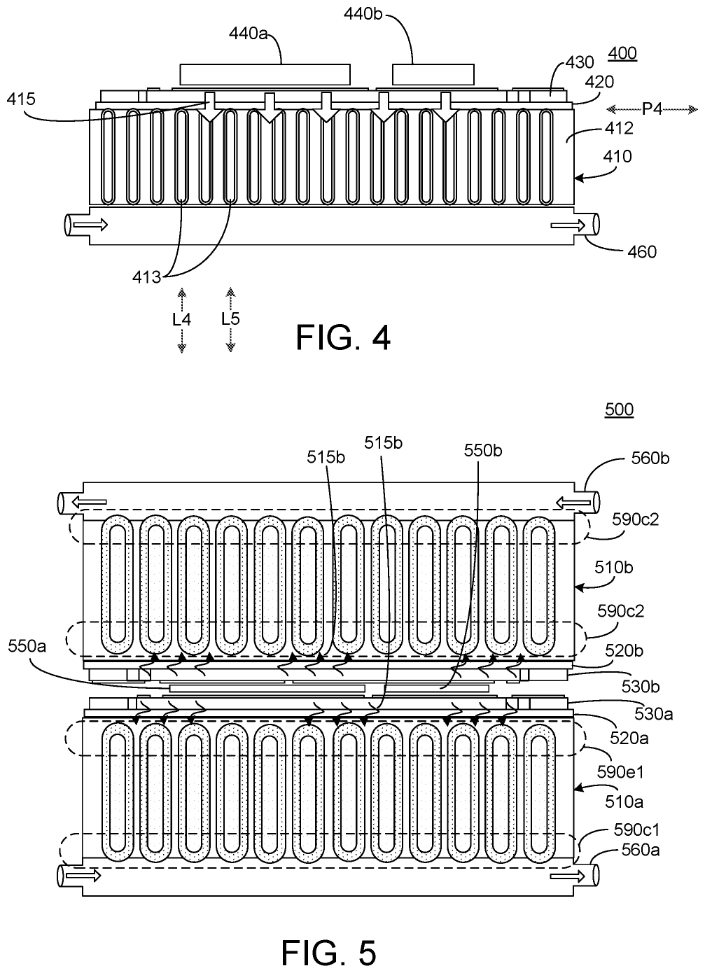

As shown in FIG. 1, the semiconductor die 140 and the spacer 150 are disposed on the patterned metal layer 130. In some implementations, the semiconductor die 140 and the spacer 150 can be soldered to the patterned metal layer 130. In some implementations, a semiconductor device assembly can include a plurality of semiconductor die and/or a plurality of spacers. In some implementations, the spacer 150 can be omitted, such as in the example implementations of FIGS. 2A, 2B and 4. The spacer 150 can be electrically conductive. For instance, the spacer 150 can be copper or a copper alloy, such as copper molybdenum.

FIGS. 2A and 2B are diagrams illustrating side views (e.g., cross-sectional side views) of an example semiconductor device assembly (assembly 200). Specifically, FIG. 2A illustrates a side view of the assembly 200, while FIG. 2B illustrates a magnified view of the inset 2B indicated in FIG. 2A. In the example implementation of FIGS. 2A and 2B, the assembly 200 includes a vacuum chamber heat pipe 210, a thermally conductive polymer layer 220, a patterned metal layer 230, a semiconductor die 240a, and a semiconductor die 240b. In this example, the semiconductor die 240a can be a power transistor, the semiconductor die 240b can be a fast-recovery diode, and the assembly 200 can be included in, or can implement a half-bridge circuit.

As shown in FIGS. 2A and 2B, the thermally conductive polymer layer 220 is disposed on a surface of the vacuum chamber heat pipe 210 that is arranged in (aligned with, situated in, etc.) a plane P1 (with P1 extending into and out of the page). The patterned metal layer 230 is disposed on the thermally conductive polymer layer 220, and the semiconductor die 240a and the semiconductor die 240b are disposed on the patterned metal layer 230. For example, the semiconductor die 240a and the semiconductor die 240 can be soldered to the patterned metal layer 230. While not shown in FIGS. 2A and 2B, the assembly 200 can also include electrical interconnections for a semiconductor device circuit that is implemented by, at least, the patterned metal layer 230, the semiconductor die 240a and the semiconductor die 240b. For instance, such electrical connections can include one or more conductive clips and/or one or more wire bonds. In some implementations, the assembly 200 can be encapsulated, e.g., at least partially encapsulated in a molding compound, such as an epoxy molding compound.

In this example, the vacuum chamber heat pipe 210 includes a metallic chamber 212 (vacuum chamber), which can be a copper chamber, an aluminum copper chamber, etc. The vacuum chamber heat pipe 210 also include an evaporatively-cooled heat pipe 213 that is disposed in the metallic chamber 212. While visible in the cross-sectional views FIGS. 2A and 2B, in an actual implementation, the evaporatively-cooled heat pipe 213 would not be visible, as it would be disposed within the metallic chamber 212. The evaporatively-cooled heat pipe 213 can include wick 214 (which can be a metallic mesh), a condensation section 216 and an evaporative section 218. The evaporatively-cooled heat pipe 213 also includes a fluid (e.g., water) that can be transported from the condensation section 216 of the evaporatively-cooled heat pipe 213 to the evaporative section 218 by the wick 214 (e.g., by capillary action).

During operation of the assembly 200, fluid in the wick 214 in the evaporative section 218 can be vaporized by absorbing heat generated, e.g., by operation of the semiconductor die 240a and the semiconductor die 240b, where the heat is absorbed via the thermally conductive polymer layer 220 and the metallic chamber 212. This heat transfer can be extremely efficient as compared to prior implementations using TIM due to high thermal conductivity of the thermally conductive polymer layer 220 (e.g., greater than or equal to 300 W/mK).

The vaporized fluid, due to vapor pressure, moves from the evaporative section 218 to the condensation section 216, where it transitions back a liquid phase and is re-absorbed by the wick 214. In this example, transition of the fluid in the evaporatively-cooled heat pipe 213 from the vapor phase to the liquid phase is facilitated, at least in part, by a fluidic cooling pipe 260, which transfers heat from the vapor phase fluid in the evaporatively-cooled heat pipe 213 to a fluid flowing in the fluidic cooling pipe 260 (e.g., as indicted by the arrows in FIG. 2A). This heat transfer is via the metallic chamber 212 and a casing (metal casing) of the fluidic cooling pipe 260.

As shown in FIG. 2A, the evaporatively-cooled heat pipe 213 is arranged along (aligned along, situated along, etc.) a longitudinal axis L1. The longitudinal axis L1 is parallel to the plane P1 of the upper surface of the vacuum chamber heat pipe 210. The assembly 200 can be referred to as implementing single-sided cooling, as a heat transfer mechanism is not included on a top side of the assembly 200 (in the views of FIGS. 2A and 2B).

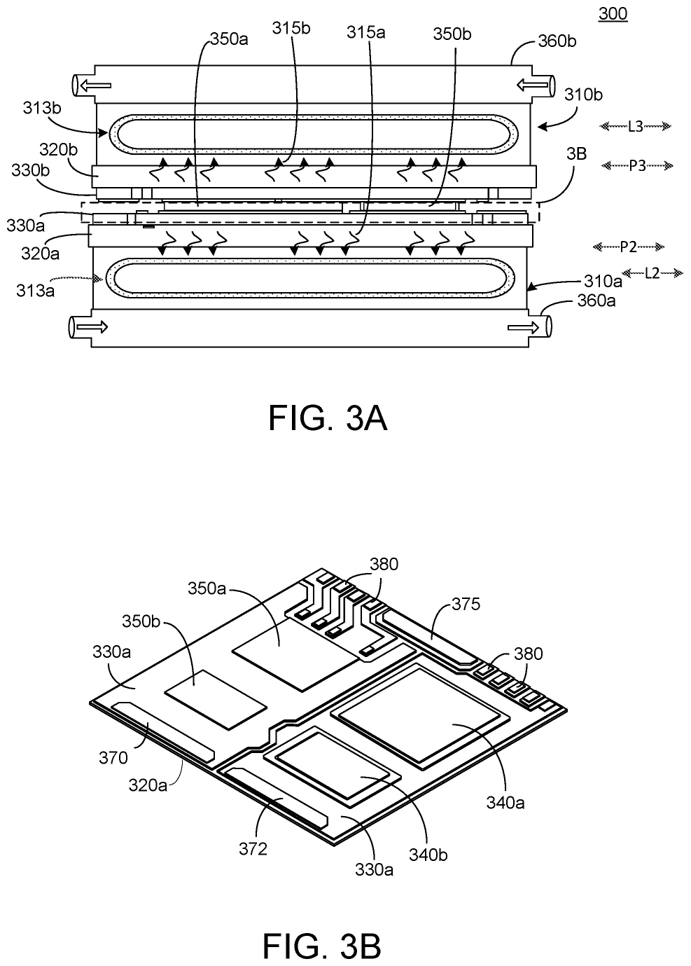

FIG. 3A is a diagram illustrating a side view (e.g., a cross-sectional side view) of another example semiconductor device assembly (assembly 300). FIG. 3B is a drawing illustrating an isometric view of a portion of the assembly 300 indicated by the inset 3B in FIG. 3A. As compared to the single-sided cooling arrangement of the assembly 200, the assembly 300 can be described as having a dual-sided cooling configuration. For instance, the assembly 300 includes a vacuum chamber heat pipe 310a and a vacuum chamber heat pipe 310b (which would not be visible in an actual implementation). A thermally conductive polymer layer 320a, such those described herein is disposed on the vacuum chamber heat pipe 310a, and a thermally conductive polymer layer 320b is disposed on the vacuum chamber heat pipe 310b. Further, a patterned metal layer 330a is disposed on the thermally conductive polymer layer 320a, and a patterned metal layer 330b is disposed on the thermally conductive polymer layer 320b.

In this example, respective portions (components, elements, etc.) of a semiconductor device circuit, such as semiconductor die, electrically conductive spacers, etc., can be disposed on the patterned metal layer 330a and the patterned metal layer 330b, an example of which is illustrated in FIG. 3B (indicated by the inset 3B). For instance, a conductive spacer 350a and a conductive spacer 350b are indicated in FIG. 3A. In some implementations, electrical connections of the circuit of the assembly 300 (e.g., using conductive clips, wire bonds, etc.) can be made, as appropriate. Cooling of the assembly 300 during its operation can be achieved from two sides of the module, e.g., a top side and a bottom side, in the view of FIG. 3A. Accordingly, the assembly 300 can be referred to as having dual-sided cooling.

As shown in FIG. 3A, surfaces of the vacuum chamber heat pipe 310a and the vacuum chamber heat pipe 310b, on which the thermally conductive polymer layer 320a and the thermally conductive polymer layer 320b are respectively formed, are arranged in (situated in, aligned in, etc.) respective planes P2 and P3, where the planes P2 and P3, are parallel to each other and extend in and out of the page. Further, the vacuum chamber heat pipe 310a includes an evaporatively-cooled heat pipe 313a that is arranged along (aligned along, situated along, etc.) a longitudinal axis L3, and the vacuum chamber heat pipe 310b includes an evaporatively-cooled heat pipe 313b that is arranged along (aligned along, situated along, etc.) a longitudinal axis L4. The longitudinal axis L3 and the longitudinal axis L4 are parallel to (parallel with, etc.) the plane P2 and the plane P3.

The evaporatively-cooled heat pipe 313a and the evaporatively-cooled heat pipe 313b can operate in similar fashion as the evaporatively-cooled heat pipe 213, as was described above. For instance, the vacuum chamber heat pipe 310a can dissipate heat conducted through the patterned metal layer 330a and the thermally conductive polymer layer 320a, e.g., as indicated by the arrows 315a in FIG. 3A. Likewise, the vacuum chamber heat pipe 310b can dissipate heat conducted through the patterned metal layer 330b and the thermally conductive polymer layer 320b, e.g., as indicated by the arrows 315b in FIG. 3A. Removal of heat transferred by the vacuum chamber heat pipe 310a and the vacuum chamber heat pipe 310b from the assembly 300 can be facilitated, respectively, by a fluidic cooling pipe 360a and a fluidic cooling pipe 360b.

FIG. 3B is a diagram illustrating a portion of the semiconductor assembly of FIG. 3A. As noted above, FIG. 3B is an isometric view of the portion of the assembly 300 indicated by the inset 3B in FIG. 3A. As shown in FIG. 3B, the patterned metal layer 330a is disposed on the thermally conductive polymer layer 320a. Further, the conductive spacer 350a and the conductive spacer 350b are disposed on a portion of the patterned metal layer 330a, while a semiconductor die 340a and a semiconductor die 340b are disposed on another portion of the patterned metal layer 330. The example of FIG. 3B also includes power tab connection pads 370, 372 and 374, which can be configured for attachment of power supply connection tabs and an output signal tab (terminals, etc.)

In this example, the semiconductor die 340a can be a power transistor and the semiconductor die 340b can be a fast-recovery diode. A complimentary portion of a corresponding semiconductor circuit can be formed on the patterned metal layer 330b of the 300. For instance, the patterned metal layer 330b can have a complimentary arrangement of semiconductor die (which are coupled with the conductive spacers 350a and 350b in the assembly 300) and conductive spacers (which are coupled with the semiconductor die 340a and the semiconductor die 340b in the assembly 300), e.g., of a half-bridge circuit. As shown in FIG. 3B, the patterned metal layer 330a can also include signal contact pads 380, which can be used for communicating signal related to operation (and monitoring operation) of a semiconductor device circuit implemented by the assembly 300.

FIG. 4 is a diagram illustrating a side view (e.g., cross-sectional side view) of yet another example semiconductor device assembly (assembly). As shown in FIG. 4, the assembly 400 includes a vacuum chamber heat pipe 410, a thermally conductive polymer layer 420, a patterned metal layer 430, a semiconductor die 440a, and a semiconductor die 440b. In this example, as with the assembly 200, the semiconductor die 440a can be a power transistor, the semiconductor die 440b can be a fast-recovery diode, and the assembly 400 can be included in, or can implement a half-bridge circuit.

As shown in FIG. 4, the thermally conductive polymer layer 420 is disposed on a surface of the vacuum chamber heat pipe 410 that is arranged in (aligned with, situated in, etc.) a plane P4 (with P4 extending into and out of the page). The patterned metal layer 430 is disposed on the thermally conductive polymer layer 420, and the semiconductor die 440a and the semiconductor die 440b are disposed on the patterned metal layer 430. In the example of FIG. 4, the vacuum chamber heat pipe 410 is disposed on a fluidic cooling pipe 460, which can remove (transfer, dissipate, etc.) thermal energy (heat indicated by the arrows 415) transferred to it by the vacuum chamber heat pipe 410.

As compared to the vacuum chamber heat pipe 210 of FIG. 2, the vacuum chamber heat pipe 410 of FIG. 4 includes a plurality of evaporatively-cooled heat pipes 413 disposed in a metallic chamber 412 that are arranged along respective longitudinal axes that are orthogonal to the plane P4 and parallel to one another (e.g., the longitudinal axes L4 and L5)), rather than the single evaporatively-cooled heat pipe 213 of the assembly 200.

In some implementations, the arrangement shown in FIG. 4 can provide certain advantages. For instance, the arrangement of the plurality of evaporatively-cooled heat pipes 413 in the metallic chamber 412 can allow for implementing a thicker vacuum chamber heat pipe 410 than the arrangement of the vacuum chamber heat pipe 210, as the parallel arranged plurality of evaporatively-cooled heat pipes 413 can be easier to produce than a single, larger evaporatively-cooled heat pipe 213. Furthermore, the arrangement of FIG. 4 can have lower thermal resistance due to the parallel arrangement of the plurality of evaporatively-cooled heat pipes 413, e.g., similar to parallel electrical resistances. The evaporative portions of the plurality of evaporatively-cooled heat pipes 413 are disposed at respective upper portions of the plurality of evaporatively-cooled heat pipes 413 as shown in FIG. 4, while the condensation portions are disposed at respective lower portions of the plurality of evaporatively-cooled heat pipes 413.

FIG. 5 is a diagram illustrating a side view (e.g., cross-sectional side view) of still another example semiconductor device assembly (assembly 500). The assembly 500, as with the assembly 300, has a dual-sided cooling configuration that includes vacuum chamber heat pipes 510a and 510b having similar configurations as the vacuum chamber heat pipe 410 of the assembly 400. In the assembly 500, a thermally conductive polymer layer 520a, such those described herein, is disposed on the vacuum chamber heat pipe 510a, and a thermally conductive polymer layer 520b is disposed on the vacuum chamber heat pipe 510b. Further, a patterned metal layer 530a is disposed on the thermally conductive polymer layer 520a, and a patterned metal layer 530b is disposed on the thermally conductive polymer layer 520b.

In this example, as with the assembly 300, respective portions (components, elements, etc.) of a semiconductor device circuit, such as semiconductor die, electrically conductive spacers, etc., can be disposed on the patterned metal layer 530a and the patterned metal layer 530b, such the example illustrated in, and described with respect to FIG. 3B. For instance, a conductive spacer 550a and a conductive spacer 550b are indicated in FIG. 5. In some implementations, electrical connections of the circuit of the assembly 500 (e.g., using conductive clips, wire bonds, etc.) can be made, as appropriate. Cooling of the assembly 500 during its operation can be achieved from two sides of the module, e.g., a top side and a bottom side, in the view of FIG. 5. Evaporative portions of the vacuum chamber heat pipes 510a and 510b are respectively indicated as evaporative portions 590e1 and 590e2, while condensations portions of the vacuum chamber heat pipes 510a and 510b are respectively indicated as evaporative portions 590c1 and 590c2 in FIG. 5.

The vacuum chamber heat pipes 510a and 510b can operate in similar fashion as the vacuum chamber heat pipe 210, the vacuum chamber heat pipe 310a, the vacuum chamber heat pipe 310b and/or the vacuum chamber heat pipe 410. For instance, the vacuum chamber heat pipe 510a can dissipate heat conducted through the patterned metal layer 530a and the thermally conductive polymer layer 520a, e.g., as indicated by the arrows 515a in FIG. 5. Likewise, the vacuum chamber heat pipe 510b can dissipate heat conducted through the patterned metal layer 530b and the thermally conductive polymer layer 520b, e.g., as indicated by the arrows 515b in FIG. 5. Removal of heat transferred by the vacuum chamber heat pipe 510a and the vacuum chamber heat pipe 510b from a circuit of the assembly 300 can be facilitated, respectively, by a fluidic cooling pipe 560a and a fluidic cooling pipe 560b.

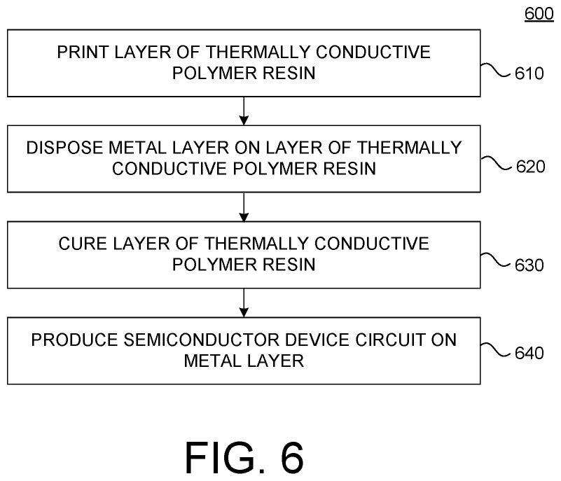

FIG. 6 is a flowchart illustrating an example method 600 for producing a semiconductor device assembly, such as the assemblies of FIGS. 1, 2A-2B, 3A, 4 and 5. For assemblies implementing dual-side cooling, such as the assembly 300 and the assembly 500, the method 600 can be performed multiple times, e.g., to form a portion of a circuit, such as in the example of FIG. 3B, on a respective thermal dissipation device. By way example and for purposes of illustration, the method 600 will be described with further reference to the assembly 100 of FIG. 1.

As shown in FIG. 6, the method 600 includes, at block 610, forming (e.g., printing) a layer of a thermally conductive polymer resin, e.g., the thermally conductive polymer compound 120, such as on a surface of a metallic chamber including an evaporative-cooled heat pipe (vacuum chamber heat pipe 110). As described herein, the thermally conductive polymer compound of block 610 can be a mixture of a viscous polymer resin and thermally conductive nanoparticles, such as those described herein. At block 620, the method includes disposing (forming, depositing, etc.) a metal layer, e.g., the patterned metal layer 130, on the layer of thermally conductive polymer resin. In some implementations, the metal layer of block 620 can be patterned prior to disposing the metal layer on the thermally conductive polymer resin, e.g., pre-patterned. In some implementations, the metal layer of block 620 can be patterned after being disposed on the thermally conductive polymer layer, e.g., in-situ patterned. For example, the metal layer can be patterned using photolithography and etch processes. The viscous resin can provide sufficient adhesion to temporarily hold the metal layer in place, e.g., prior to curing the resin.

At block 630, the method 600 includes curing the layer of thermally conductive polymer resin. The curing at block 630 can also adhere (fixedly couple, permanently adhere, etc.) the metal layer to the thermally conductive polymer layer. As described herein, curing the thermally conductive polymer resin at block 630 can be done at a temperature between 200 and 500° C. At block 640, after the curing operation of block 630, the method 600 includes forming a semiconductor device circuit on the metal layer of block 620. In some implementations, producing the semiconductor device circuit can include in-situ patterning of the metal layer (e.g., if not pre-patterned) to produce a patterned metal layer, coupling at least one semiconductor die with the patterned metal layer; and forming electrical connections of the semiconductor device circuit. Coupling the at least one semiconductor die with the patterned metal layer can include soldering the at least one semiconductor die. Forming electrical connections can include coupling (e.g., soldering) at least one conductive clip to the patterned metal layer and/or the at least one semiconductor die. In some implementations, forming electrical connections can also include forming one or more wire bonds between the patterned metal layer and the at least one semiconductor die.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

While certain features of the described implementations have been illustrated as described herein, many modifications, substitutions, changes and equivalents will now occur to those skilled in the art. For instance, features illustrated and/or aspects described with respect to one implementation can, where appropriate, also be included in, and/or apply to other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A semiconductor device assembly comprising:
a metallic chamber configured to transfer thermal energy from a first surface of the metallic chamber to a second surface of the metallic chamber opposite the first surface;
a thermally conductive polymer layer disposed on the first surface of the metallic chamber;
a patterned metal layer disposed on the thermally conductive polymer layer; and
at least one semiconductor die disposed on the patterned metal layer.

2. The semiconductor device assembly of claim 1, wherein the thermally conductive polymer layer includes:
a cured polymer resin; and
thermally conductive nanoparticles.

3. The semiconductor device assembly of claim 2, wherein the thermally conductive nanoparticles include ceramic nanoparticles.

4. The semiconductor device assembly of claim 2, wherein the thermally conductive nanoparticles include graphite nanoparticles.

5. The semiconductor device assembly of claim 1, wherein the metallic chamber includes:
a vacuum chamber; and
an evaporative-cooled heat pipe disposed in the vacuum chamber.

6. The semiconductor device assembly of claim 5, wherein:
the first surface of the metallic chamber is arranged in a plane, and
the evaporative-cooled heat pipe is arranged along a longitudinal axis parallel to the plane.

7. The semiconductor device assembly of claim 5, wherein:
the first surface of the metallic chamber is arranged in a plane;
the evaporative-cooled heat pipe is a first evaporative-cooled heat pipe;
the metallic chamber further including:
a second evaporative-cooled heat pipe,
the first evaporative-cooled heat pipe being arranged along a first longitudinal axis orthogonal to the plane, and
the second evaporative-cooled heat pipe being arranged along a second longitudinal axis parallel to the first longitudinal axis.

8. The semiconductor device assembly of claim 1, further comprising a fluidic cooling jacket disposed on the second surface of the metallic chamber.

9. A semiconductor device assembly comprising:
a first metallic chamber configured to transfer thermal energy from a first surface of the first metallic chamber to a second surface of the first metallic chamber opposite the first surface;
a second metallic chamber configured to transfer thermal energy from a first surface of the second metallic chamber to a second surface of the second metallic chamber opposite the first surface;
a first thermally conductive polymer layer disposed on the first surface of the first metallic chamber;
a second thermally conductive polymer layer disposed on the first surface of the second metallic chamber;
a first patterned metal layer disposed on the first thermally conductive polymer layer;
a second patterned metal layer disposed on the second thermally conductive polymer layer;
a first semiconductor die disposed on the first patterned metal layer.
a second semiconductor die disposed on the second patterned metal layer;
a first electrically conductive spacer disposed on the first patterned metal layer and electrically coupled with the second semiconductor die; and
a second electrically conductive spacer disposed on the second patterned metal layer and electrically coupled with the first semiconductor die.

10. The semiconductor device assembly of claim 9, wherein the first thermally conductive polymer layer and the second thermally conductive polymer layer include:
a cured polymer resin; and
thermally conductive nanoparticles.

11. The semiconductor device assembly of claim 10, wherein the thermally conductive nanoparticles include at least one of ceramic nanoparticles or graphite nanoparticles.

12. The semiconductor device assembly of claim 9, wherein:
the first metallic chamber includes:
a first vacuum chamber; and
a first evaporative-cooled heat pipe disposed in the first vacuum chamber; and
the second metallic chamber includes:
a second vacuum chamber; and
a second evaporative-cooled heat pipe disposed in the second vacuum chamber.

13. The semiconductor device assembly of claim 12, wherein:
the first surface of the first metallic chamber is arranged in a plane,
the first evaporative-cooled heat pipe is arranged along a first longitudinal axis parallel to the plane; and
the second evaporative-cooled heat pipe is arranged along a second longitudinal axis parallel to the plane.

14. The semiconductor device assembly of claim 12, wherein:
the first surface of the first metallic chamber is arranged in a plane;
the first evaporative-cooled heat pipe is arranged along a first longitudinal axis orthogonal to the plane, and
the second evaporative-cooled heat pipe is arranged along a second longitudinal axis orthogonal to the plane.

15. The semiconductor device assembly of claim 12, wherein:
the first metallic chamber further includes a third evaporative-cooled heat pipe disposed in the first vacuum chamber; and
the second metallic chamber includes a fourth evaporative-cooled heat pipe disposed in the second vacuum chamber,
the first evaporative-cooled heat pipe, the second evaporative-cooled heat pipe, the third evaporative-cooled heat pipe and the fourth evaporative-cooled heat pipe being arranged along respective longitudinal axes that are parallel to one another.

16. The semiconductor device assembly of claim 15, wherein:
the first surface of the first metallic chamber is arranged in a plane, and
the respective longitudinal axes are orthogonal to the plane.

17. The semiconductor device assembly of claim 9, further comprising:
a first fluidic cooling jacket disposed on the second surface of the first metallic chamber; and
a second fluidic cooling jacket disposed on the second surface of the second metallic chamber.

18. A method for producing a semiconductor device assembly, the method comprising:
forming, on a surface of a metallic chamber including an evaporative-cooled heat pipe, a layer of thermally conductive polymer resin;
disposing a metal layer on the layer of thermally conductive polymer resin;
curing the layer of thermally conductive polymer resin; and
after curing the layer of thermally conductive polymer resin, producing a semiconductor device circuit on the metal layer.

19. The method of claim 18, wherein producing the semiconductor device circuit includes:
patterning the metal layer to produce a patterned metal layer;
coupling at least one semiconductor die with the patterned metal layer; and
forming electrical connections of the semiconductor device circuit.

20. The method of claim 18, wherein curing the layer of thermally conductive polymer resin adheres the metal layer to the layer of thermally conductive polymer resin.
